(19) United States
(12) Patent Application Publication
(10) Pub. No.: US 2013/0284215 A1
(43) Pub. Date: Oct. 31, 2013

(54) METHODS AND APPARATUS FOR ISOLATING A RUNNING BEAM CONVEYOR FROM A SEMICONDUCTOR SUBSTRATE CLEANING ENVIRONMENT

(71) Applicant: APPLIED MATERIALS, INC., Santa Clara, CA (US)

(72) Inventors: Andrew Liu, Milpitas, CA (US); Hui Chen, Burlingame, CA (US)

(21) Appl. No.: 13/873,008

(22) Filed: Apr. 29, 2013

Related U.S. Application Data
(60) Provisional application No. 61/640,000, filed on Apr. 30, 2012.

(51) Int. Cl. H01L 21/677; B65G 49/00

(52) U.S. Cl. CPC H01L 21/67736; B65G 49/00
USPC 134/137; 29/428; 198/860.1

(57) ABSTRACT

In one aspect, a substrate cleaning system is provided. The substrate cleaning system includes a plurality of cleaning modules; a conveyor for transporting a substrate between the cleaning modules; and a partition assembly that isolates the cleaning modules from the conveyor. Apparatus and methods for isolating CMP cleaning modules from a conveyor are provided, as are numerous other aspects.

### RELATED APPLICATIONS

The present application claims priority from U.S. patent application Ser. No. 61/640,000, filed Apr. 30, 2012, entitled “METHODS AND APPARATUS FOR ISOLATING A RUNNING BEAM CONVEYOR FROM A SEMICONDUCTOR SUBSTRATE CLEANING ENVIRONMENT” (Attorney Docket No. 16939/L) which is hereby incorporated herein by reference in its entirety for all purposes.

### FIELD

The present invention generally relates to semiconductor substrate cleaning systems, and more particularly is directed to methods and apparatus for isolating a conveyor from the operating environment of a semiconductor substrate cleaning system.

### BACKGROUND

Existing chemical mechanical planarization (CMP) systems including pre-CMP substrate cleaning modules may use a running beam conveyor to move substrates from a factory interface to the cleaning modules and to the CMP polisher. Particle contamination of the substrates can interfere with CMP processing and result in undesirable polishing results. Thus, what are needed are methods and apparatus for reducing the possibility of particle contamination of the cleaning environment in which the CMP system is operated.

### SUMMARY

In a first aspect, a substrate cleaning assembly is provided. The substrate cleaning assembly includes a plurality of cleaning modules; a conveyor for transporting a substrate between the cleaning modules; and a partition assembly that isolates the cleaning modules from the conveyor.

In another aspect, a substrate cleaning apparatus is provided. The substrate cleaning apparatus isolates cleaning modules from a substrate conveyor, for example, in a CMP cleaning system. The apparatus includes a support; a rail below the support; and a partition held by the support on the rail, the partition configured to be disposed between a conveyor for transporting a substrate and a plurality of cleaning modules, and to isolate the cleaning modules from the conveyor.

In yet another aspect, a method of operating a substrate cleaning system is provided. The method involves isolating cleaning modules of a substrate polishing system from a conveyor. The method includes providing a plurality of cleaning modules disposed adjacent to each other; providing a conveyor for transporting a substrate between the cleaning modules; and isolating the cleaning modules from the conveyor by disposing a partition between the conveyor and the cleaning modules.

Numerous other aspects are provided. Other features and aspects of the present invention will become more fully apparent from the following detailed description, the appended claims and the accompanying drawings.

### BRIEF DESCRIPTION OF THE DRAWINGS

FIG. 1 is a schematic block diagram depicting an example CMP cleaning system according to some embodiments of the present invention.

FIG. 2 is a perspective diagram depicting an example CMP cleaning system according to some embodiments of the present invention.

FIG. 3 is a cross-sectional view depicting an example CMP cleaning system according to some embodiments of the present invention.

FIG. 4 is a perspective diagram depicting an example outer partition of a CMP cleaning system according to some embodiments of the present invention.

FIG. 5 is a magnified perspective diagram depicting details of an upper portion of the example outer partition of FIG. 4 according to some embodiments of the present invention.

FIG. 6 is a magnified perspective diagram depicting details of the portion of the example outer partition in the area labeled A in FIG. 5 according to some embodiments of the present invention.

FIG. 7 is a magnified perspective diagram depicting details of a lower portion of an example outer partition of a CMP cleaning system according to some embodiments of the present invention.

FIG. 8 is a perspective diagram depicting an example inner partition of a CMP cleaning system according to some embodiments of the present invention.

FIG. 9 is a cross-sectional diagram depicting features of an example inner partition of a CMP cleaning system according to some embodiments of the present invention.

### DETAILED DESCRIPTION

Inventive embodiments of methods and apparatus are provided for isolating a running beam conveyor of a CMP cleaning system from the cleaning environment in which the CMP cleaning system is operated. The inventors of the present invention have noticed that the running beam conveyor used to move substrates from the factory interface to the cleaning modules and to the CMP polisher is a potential source of particle contaminants on processed substrates. Specifically, the actuators, motor drive, and other mechanical parts of the running beam conveyor that physically interact, generate particles (e.g., due to friction) and thus, may contaminate the adjacent cleaning modules and the substrates. In some embodiments, the present invention provides methods and apparatus to partition and isolate the running beam conveyor from the remainder of the cleaning system. In some embodiments, a series of interlocking, removable, partition panels are used to surround the running beam conveyor and to isolate the conveyor.

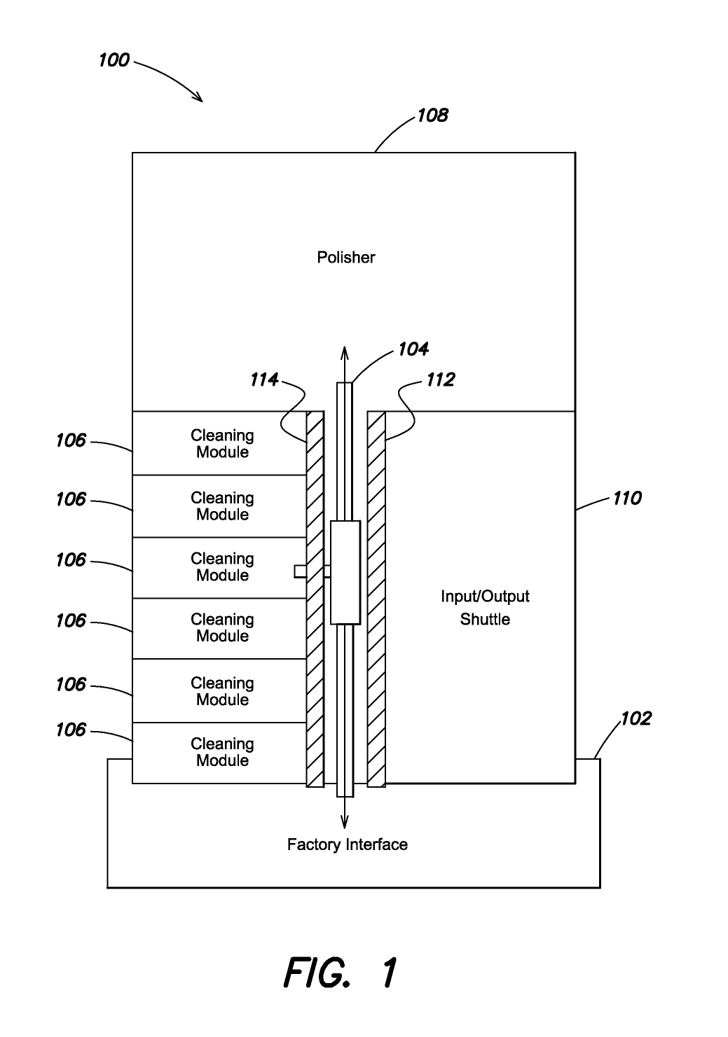

Turning to FIG. 1, an example CMP cleaning system 100 according to the present invention is depicted as a top-view schematic block diagram. The system 100 includes a factory interface 102 for loading and unloading substrates from the system 100. The factory interface 102 may include various robots and load ports adapted to receive substrates to be processed and to present substrates that have been processed (e.g., cleaned, planarized, and polished). A running beam conveyor 104 is adapted to move substrates from and to the factory interface 102. The running beam conveyor is also adapted to move substrates through and between the various cleaning modules 106 and the CMP polisher 108. The system 100 also includes an input/output shuttle 110 disposed between the factory interface 102 and the polisher 108. Disposed on either side of the running beam conveyor 104 and extending from the factory interface 102 to the polisher 108, are an inner partition 112 and an outer partition 114. The partitions 112, 114 are configured to provide a barrier between the running beam conveyor 104 and the cleaning modules 106 to prevent any particles generated by the operation of the running beam conveyor 104 from entering the cleaning modules 106 and thereby potentially contaminating substrates being processed within the cleaning modules 106. The partitions 112, 114 are described below in more detail.

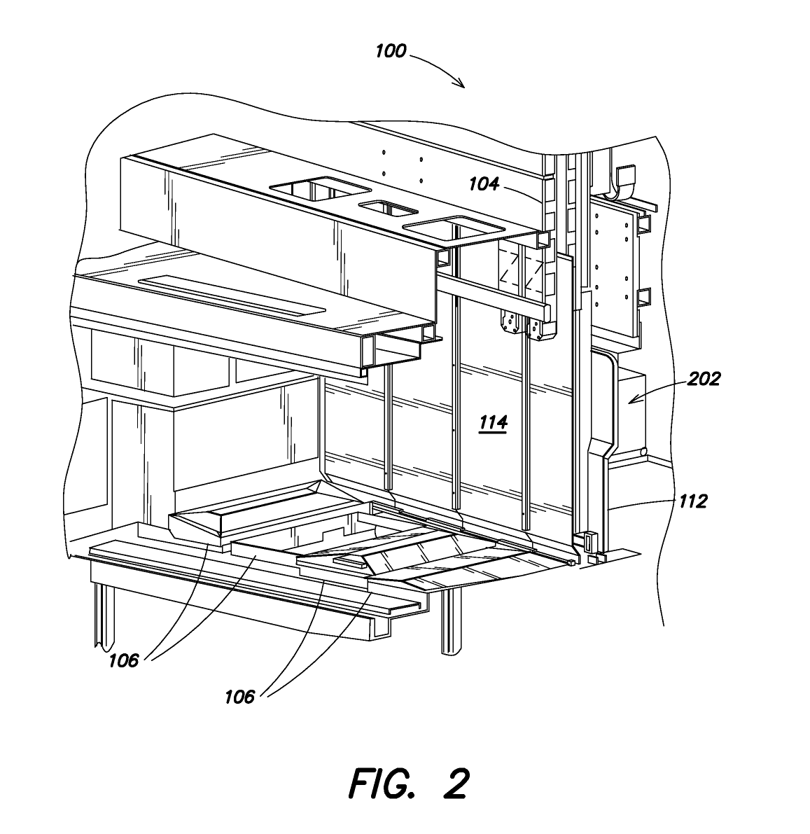

FIG. 2 depicts the CMP cleaning system 100 in a cross-sectional perspective view with the factory interface 102 not present. The tops of the cleaning modules 106 are seen in the foreground and the outer partition 114 is disposed next to the cleaning modules 106. The running beam conveyor 104 is shown isolated from the cleaning modules 106 between the outer partition 114 and the inner partition 112. A pass through 202 is shown on the far side of the inner partition 112.

As can be seen in FIG. 2, the depicted example embodiment of the outer partition 114 includes a number of panels (e.g., four) coupled together to form the partition 114. Likewise, the inner partition 112 can be so formed. In some embodiments, multiple panels can be used to form the partitions 112, 114 and in other embodiments, a single panel can be used. By providing a partition 112, 114 that uses multiple panels however, the system 100 remains modular and any length partition can be assembled to accommodate any number of cleaning modules 106. Thus, for example, in some embodiments, the partition panels can be wide enough to span the width of a single cleaning module 106 such that the total width of the assembled partitions 112, 114 can be configured to match the length of the line of cleaning modules 106 by adding a pair of panels (one for each partition 112, 114) for each cleaning module in the system.

In the particular example embodiment shown in FIG. 2, the outer partition 114 includes four panels and each panel is approximately 338 mm wide and approximately 924 mm high. Thus, the outer partition 114 formed by the four panels assembled together is approximately 1352 mm wide and approximately 924 mm high. Other size panels can be used. For example, two panels with a width of approximately 676 mm can be used to form an outer partition 114 of the same size. Likewise, the inner partition 112 can be so formed.

In some embodiments, the partition panels can be constructed from polyvinyl chloride (PVC) or other suitable material. Clear PVC can be used to allow viewing of operation of the running beam conveyor 104 and other components. PVC in particular is suitable and compatible with clean room applications and can be manufactured to meet the FM4910 Fire-Safe Plastics standard. Other materials meeting this standard and being compatible with clean room applications can also be used.

The thickness of the material used to manufacture the panels can be selected to provide good durability, structural integrity, and still be relatively light weight. In some embodiments, approximately ⅜ inch thick material can be used. Other thicknesses can be used in other embodiments.

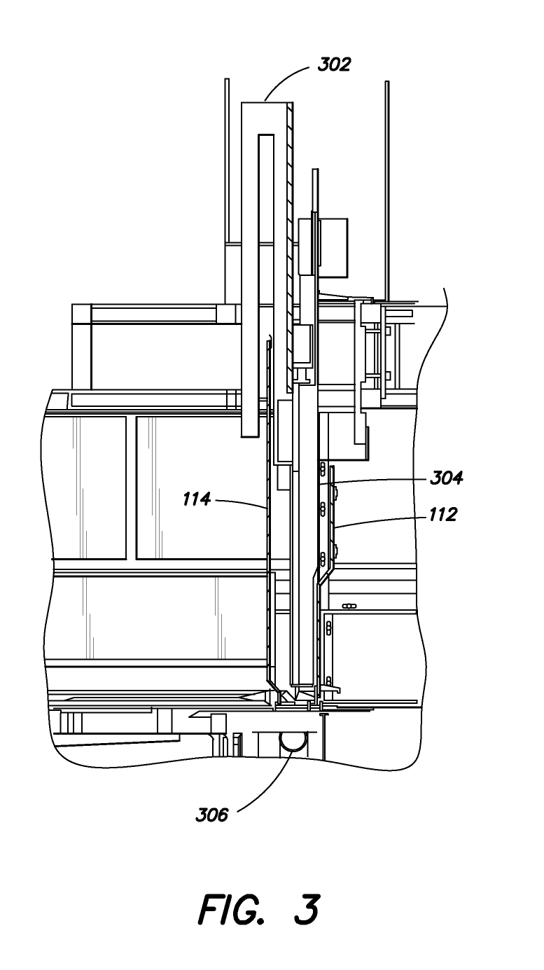

Turning now to FIG. 3, a cross-sectional end-view of the CMP cleaning system 100 is depicted from the factory interface 102 end of the system 100. The running beam conveyor 104 (FIG. 2) can be more clearly seen between the outer partition 114 and the inner partition 112. FIG. 3 also illustrates a substrate gripper 302 (e.g., a U-shaped gripper) adapted to hold the substrates during conveyance and to pick-up individual substrates from the cleaning modules 106. The example embodiment of a substrate gripper 302 shown in FIG. 3 extends over the outer partition 114 to access the cleaning modules 106.

The running beam driver 304 (e.g., an actuator for the conveyor 104) is shown disposed between the outer partition 114 and the inner partition 112. An exhaust port 306 for the running beam conveyor is provided to vent the particles generated by the driver 304 and other moving parts. In some embodiments, a down draft, vacuum pressure may be provided at the exhaust port to pull any particles from the running beam conveyor 104 out of the system 100. Thus, in some embodiments, the panels of the partitions 112 and 114 can be coupled together to create a seal that allows a negative vacuum pressure to be established between the partitions 112, 114.

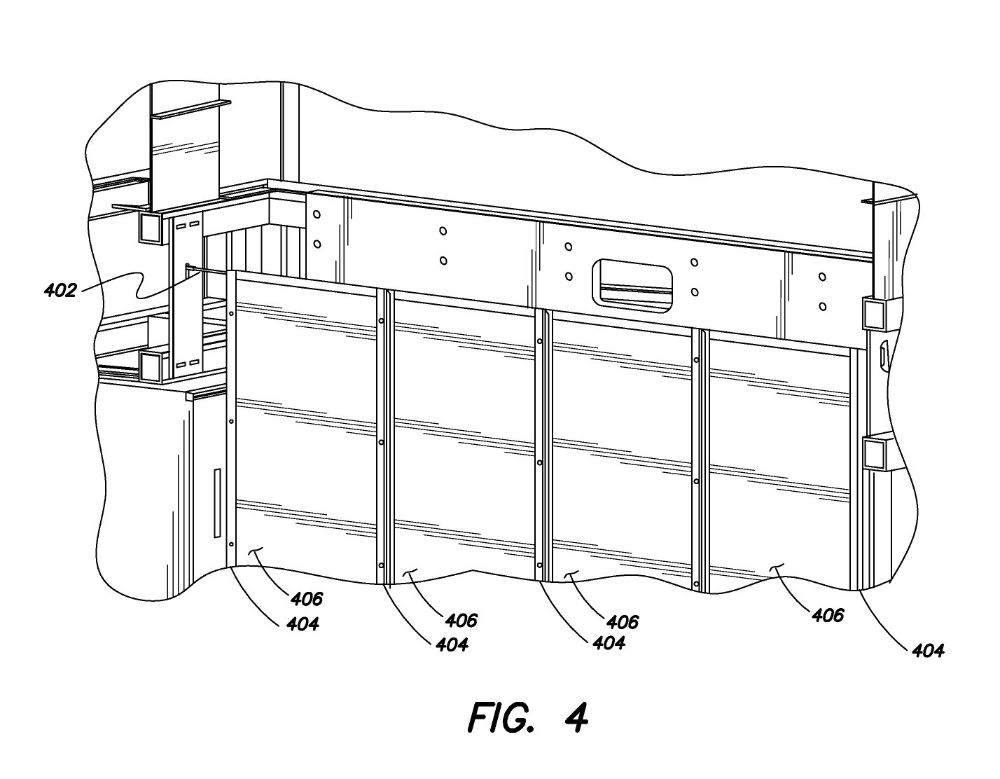

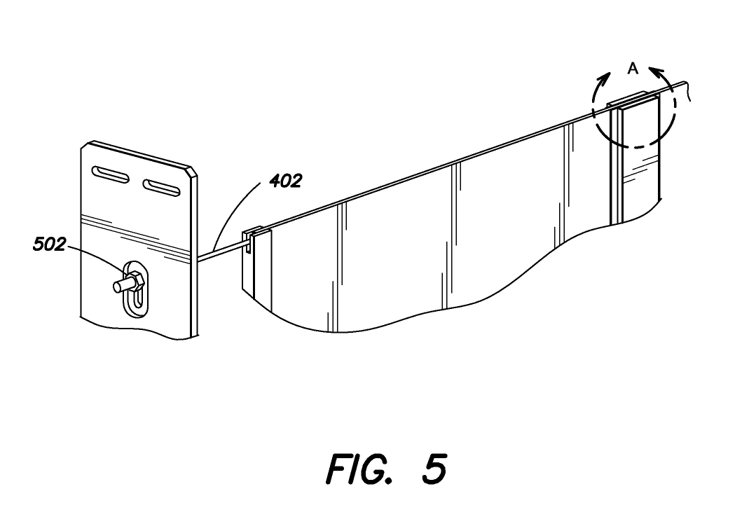

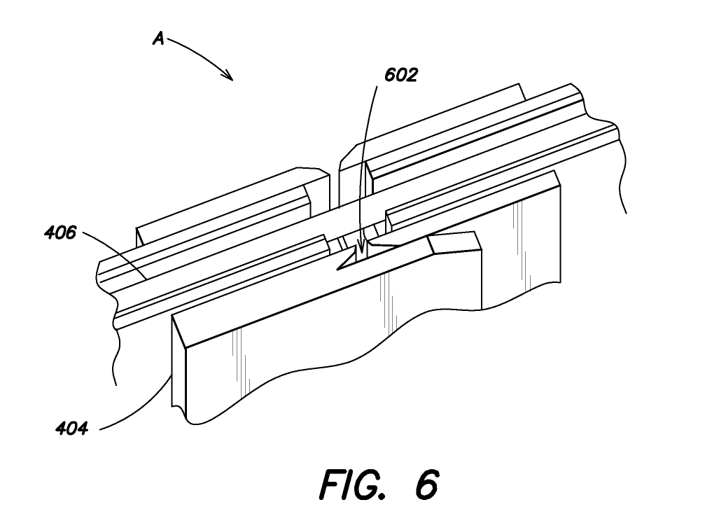

Turning to FIG. 4, details of the outer partition 114 are illustrated in a partial perspective view of the system 100. In some embodiments, a stainless steel (SST) supporting wire 402 supports an arrangement of SST frames 404 and a series of interlocking panels 406. Other materials may be used. As shown in FIG. 5, the supporting wire 402 is tensioned using a fastener 502 (e.g., a tightening nut on a threaded end of the supporting wire 402). FIG. 6 is a magnified perspective diagram depicting the portion of FIG. 5 labeled A. Area A illustrates an over-lapping, inter-locking joint 602 between the frames 404 and the panels 406. This inter-locking joint 602 allows the panels 406 to be sealably coupled together to contain any contaminates and to prevent any airflow through the partition 114.

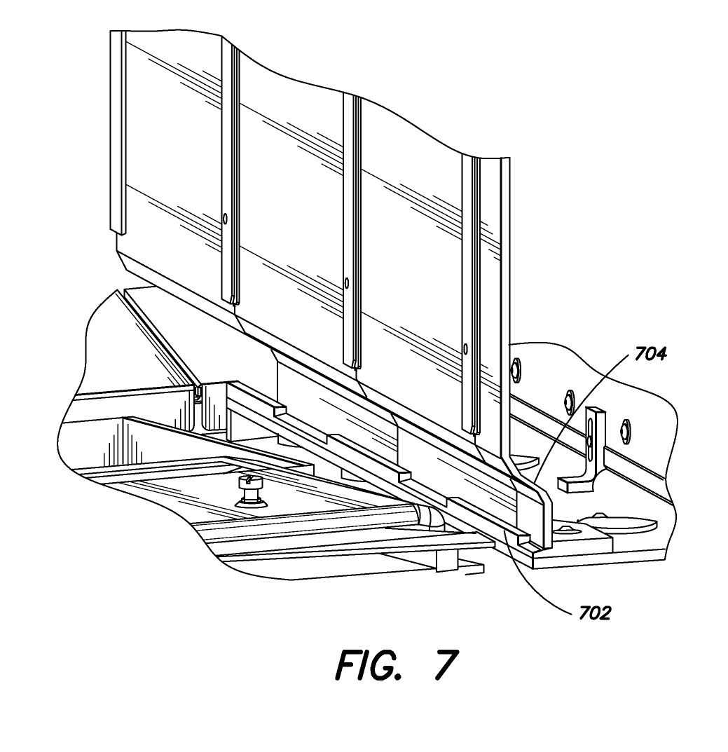

FIG. 7 is a magnified perspective diagram depicting the lower portion of the outer partition 114. A sealing member (e.g., a rubber seal) may be provided along the base of the outer partition 114 to seal the bottom of the partition 114 against the support rail 702. In some embodiments, the outer partition 704 may include a clearance contour 704 to provide improved access to the cleaning modules 106. For example, the clearance contour 704 in the embodiment shown in FIG. 7 bends away from the major surface of the panel 406 at approximately 54 degrees and extends away from the major surface approximately 25 mm. This clearance contour 704 provides a space immediately above and adjacent to the cleaning modules 106 (FIG. 2), i.e., for substrate handling, gripper 302 (FIG. 3) clearance, and/or cleaning module 106 operation. Although only a single clearance contour 704 is depicted on the outer partition 114 in the particular example embodiment shown in the drawings, any number of clearance contours can be provided on either partition 112, 114 to accommodate operation of stationary and moving parts of the system 100. In other words, the partitions 112, 114 can have any shape needed to accommodate the system 100.

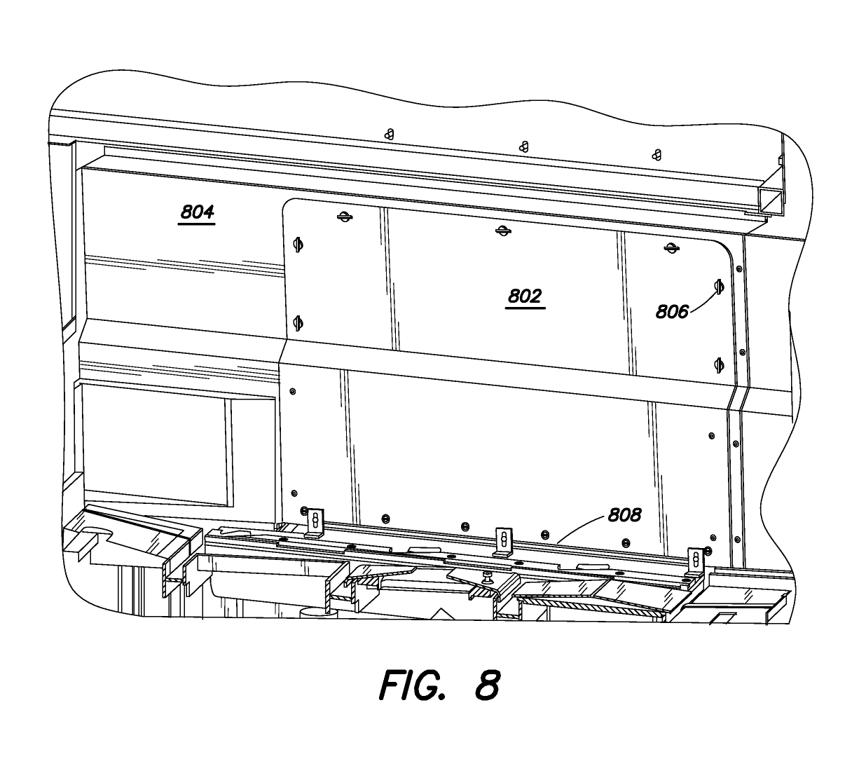

FIG. 8 provides a perspective view of an example embodiment of an inner partition 112. The inner partition 112 may include a removable, sealable access window 802 supported by a frame 804. In some embodiments, the frame may be constructed of SST and the window may be constructed of clear PVC. A series of fasteners 806 disposed around the perimeter may be used to hold the window 802 in place and a seal 808 (i.e., a rubber seal) may be provided at the lower edge of the window 802. The fasteners 806 may be, for example, quarter turn fasteners made of black nylon and commercially available from Southco, Inc. of Concordville, Pa.

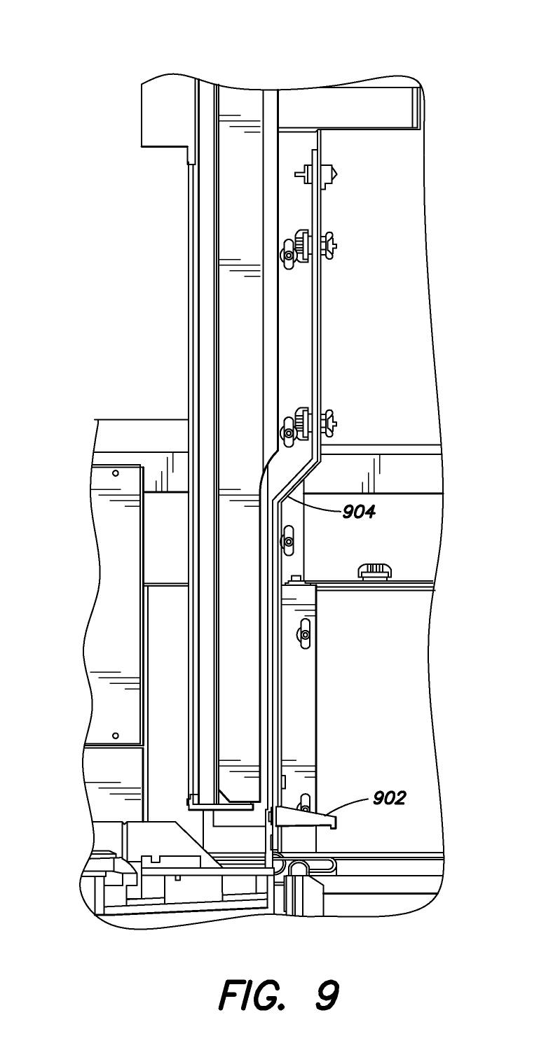

FIG. 9 is a cross-sectional diagram depicting an end view of an embodiment of the inner partition 112. In some embodiments, the inner partition 112 can include a drip rail 902 along the lower edge of the base of the partition 112 as illustrated in FIG. 9. The example drip rail 902 depicted extends from the inner partition 112 at an angle of approximately 78 degrees and reaches approximately 48 mm from the mounting surface on the inner partition 112. As discussed above, in some embodiments, the inner partition 112 may also include one or more a contours 904 to accommodate other components (e.g., the running beam conveyor 104) of the system 100.

Accordingly, while the present invention has been disclosed in connection with the preferred embodiments thereof, it should be understood that other embodiments may fall within the scope of the invention, as defined by the following claims.

The invention claimed is:

1. A substrate cleaning system, comprising:
a plurality of cleaning modules;
a conveyor for transporting a substrate between the cleaning modules; and
a partition assembly that isolates the cleaning modules from the conveyor.

2. The substrate cleaning system of claim 1, wherein the partition assembly includes an inner partition and an outer partition, and wherein the inner partition and an outer partition surround the conveyor.

3. The substrate cleaning system of claim 1 further comprising a factory interface and a chemical mechanical planarization (CMP) polisher coupled to opposite ends of the conveyor, and wherein the partition assembly extends from the factory interface to the CMP polisher.

4. The substrate cleaning system of claim 1 wherein the partition assembly includes a plurality of panels disposed vertically and sealable together.

5. The substrate cleaning system of claim 1 wherein the partition assembly includes one or more clearance contours and is coupled to a down draft vacuum source.

6. An apparatus for isolating cleaning modules from a substrate conveyor in a CMP cleaning system, the apparatus comprising:
a support;
a rail below the support; and
a partition held by the support on the rail, the partition configured to be disposed between a conveyor for transporting a substrate and a plurality of cleaning modules, and to isolate the cleaning modules from the conveyor.

7. The apparatus of claim 6, wherein the partition includes an inner partition and an outer partition, and wherein the inner partition and an outer partition surround the conveyor.

8. The apparatus of claim 6 wherein the partition extends from a factory interface to a chemical mechanical planarization (CMP) polisher coupled to opposite ends of the conveyor.

9. The apparatus of claim 6 wherein the partition includes a plurality of panels disposed vertically and sealable together.

10. The apparatus of claim 6 wherein the partition includes one or more clearance contours.

11. A method of isolating cleaning modules of a substrate polishing system from a conveyor, the method comprising:
providing a plurality of cleaning modules disposed adjacent to each other;
providing a conveyor for transporting a substrate between the cleaning modules; and
isolating the cleaning modules from the conveyor by disposing a partition between the conveyor and the cleaning modules.

12. The method of claim 11, wherein isolating the cleaning modules from the conveyor by disposing a partition between the conveyor and the cleaning modules includes surrounding the conveyor with an inner partition and an outer partition.

13. The method of claim 12 wherein surrounding the conveyor with an inner partition and an outer partition includes applying a vacuum between the inner partition and the outer partition.

14. The method of claim 11 further comprising extending the partition from a factory interface to a chemical mechanical planarization (CMP) polisher coupled to opposite ends of the conveyor.

15. The method of claim 11 wherein isolating the cleaning modules from the conveyor includes providing a partition that includes a plurality of panels disposed vertically and sealable together.
